(19) United States
(12) Patent Application Publication
(10) Pub. No.: US 2017/0265305 A1
(43) Pub. Date: Sep. 14, 2017

(54) POPULATED PRINTED CIRCUIT BOARD AND METHOD FOR POPULATING A PRINTED CIRCUIT BOARD

(71) Applicant: BorgWarner Ludwigsburg GmbH, Ludwigsburg (DE)

(72) Inventors: Sisay Tadele, Friolzheim (DE); Michael Störzinger, Bretten (DE); Helmut Hoppe, Stuttgart (DE); Alexander Dauth, Maulbronn (DE); Riza Oguz, Esslingen (DE); Andreas Bäumer, Bretten-Bauerbach (DE); Markus Wetzel, Filderstadt (DE)

(21) Appl. No.: 15/448,904

(22) Filed: Mar. 3, 2017

(30) Foreign Application Priority Data
Mar. 10, 2016 (DE) 10 2016 104 424.5

(51) Int. Cl. H05K 1/18; H05K 1/11; H05K 3/34

(52) U.S. Cl. CPC H05K 1/181; H05K 3/341; H05K 1/111; H05K 2201/10166; H05K 2201/10181; H05K 2203/04; H05K 2201/10265

(57) ABSTRACT

Disclosed is a printed circuit board having at least one power semiconductor soldered thereon and, as a thermal fuse, a spring having two contact arms fastened to solder pads of the printed circuit board by soldered connections. The spring is under mechanical stress such that at least one of the two contact arms moves away from one of the solder pads by spring force as soon as the soldered connection loses its strength and fails due to overheating. The soldered connection of at least one of the contact arms loses its strength at a lower temperature and is formed from a different alloy than the soldered connection that connects the power semiconductor to the printed circuit board. A method for populating a printed circuit board is also described.

### RELATED APPLICATIONS

This applications claims priority to DE 10 2016 104 424.5, filed Mar. 10, 2016, the entire disclosure of which is hereby incorporated herein by reference in its entirety.

### BACKGROUND AND SUMMARY

It is known from U.S. Publication No. 2016/0049275 to provide printed circuit boards with thermal fuses, which are formed from a spring that is soldered to the printed circuit board in a prestressed manner via the two contact arms of the spring. When the solder loses its strength as a result of overheating, at least one of the contact arms detaches from the relevant solder pad of the printed circuit board owing to the prestress. In this manner, the circuit is broken on overheating.

This disclosure teaches a way to protect an electrical circuit on the printed circuit board even better by means of a thermal fuse.

A printed circuit board according to this disclosure bears an electrical circuit and, as the thermal fuse, a prestressed spring. The electrical circuit comprises at least one power semiconductor, e.g., a MOSFET transistor, soldered thereon and may comprise any number of other circuit elements. For example, the electrical circuit can be a control circuit of a glow plug control device or a control circuit for a motor vehicle heating system.

The thermal fuse is a spring in the form of a contact bridge. The spring has two contact arms, which are fastened to the printed circuit board by means of a soldered connection. The spring is under mechanical stress such that at least one of the two contact arms moves away from the relevant contact area of the printed circuit board by spring force as soon as the soldered connection loses its strength owing to overheating. According to this disclosure, the soldered connection of at least one of the contact arms comprises a different material than the soldered connection of the other circuit elements, in particular, a different material than the at least one soldered-on power semiconductor. Specifically, the soldered connection of at least one of the contact arms loses its strength and melts at a lower temperature than the soldered connection that connects the at least one power semiconductor to the printed circuit board and other circuit elements. In this manner, the thermal fuse responds in the event of overheating so early that detachment of further components of the circuit is avoided.

In an advantageous refinement of this disclosure, the soldered connection of at least one of the contact arms loses its strength and melts at a temperature at least 10 K lower than the soldered connection that connects the power semiconductor to the printed circuit board. The soldered connection of at least one of the contact arms preferably loses its strength and melts at a temperature at least 20 K lower than the soldered connection that connects the power semiconductor to the printed circuit board.

In a further advantageous development of this disclosure, the spring is fastened to a support, which is fastened to the printed circuit board by means of retaining elements. The retaining elements of the support can for example be in the form of pins or strips and be for example plugged into the printed circuit board and/or soldered to the printed circuit board, the corresponding soldered connection losing its strength at a higher temperature than the soldered connection of at least one of the contact arms. If the fuse trips, that is, one of the contact arms detaches from the relevant contact area of the printed circuit board, the spring is still retained by the support. This advantageously prevents the spring that is lying loosely on the printed circuit board moving in an uncontrolled manner and causing a short circuit.

The support can for example have a lower part, which is bridged by the spring, and an upper part, which is fastened to the lower part. The spring is then retained between the lower part and the upper part of the support. The lower part preferably has cut-outs in which the soldered ends of the contact arms are arranged. For example, the lower part can have an H-shaped main face. Alternatively, a single-part support can be used to fasten the spring to the printed circuit board, for example a snap clip.

Soldered connections that lose their strength at different temperatures can be implemented by using different solder materials or alloys for at least one of the two contact arms of the spring and for the other soldered connections of the printed circuit board. For example, corresponding solder pad of the printed circuit board can be printed with higher-melting solder or lower-melting solder, depending on the function. Another possibility consists in applying higher-melting solder material to all the solder pad of the printed circuit board and then additionally applying lower-melting solder material to the solder pads, the soldered connection of which is intended to lose its strength at lower temperatures. In the soldered connection created in this manner, two layers of different solder material can then lie one on top of the other, or mixing of the two solder materials can occur during the soldering process, for example by reflow soldering, and therefore this mixture then loses its strength at a lower temperature than the higher-melting solder material.

As the first solder material, higher-melting solder material can be applied to the printed circuit board for example by printing, in particular by means of a doctor method using a paste stencil. The second, lower-melting solder material can likewise be printed, for example by a method without a stencil, such as a jet paste printing method or a needle dispensing method.

### BRIEF DESCRIPTION OF THE DRAWINGS

The above-mentioned aspects of exemplary embodiments will become more apparent and will be better understood by reference to the following description of the embodiments taken in conjunction with the accompanying drawings, wherein:

FIG. 1 shows a printed circuit board having a spring as a thermal fuse;

FIG. 2 shows the spring as the thermal fuse with support and fastening elements;

FIG. 3 shows a further view of FIG. 2, showing the underside that faces the printed circuit board;

FIG. 4 shows a view of FIG. 2 with the upper part of the support removed;

FIG. 5 shows the spring and the retaining elements; and

FIG. 6 shows fields of the printed circuit board covered with solder.

### DESCRIPTION

The embodiments described below are not intended to be exhaustive or to limit the invention to the precise forms disclosed in the following detailed description. Rather, the embodiments are chosen and described so that others skilled in the art may appreciate and understand the principles and practices of this disclosure.

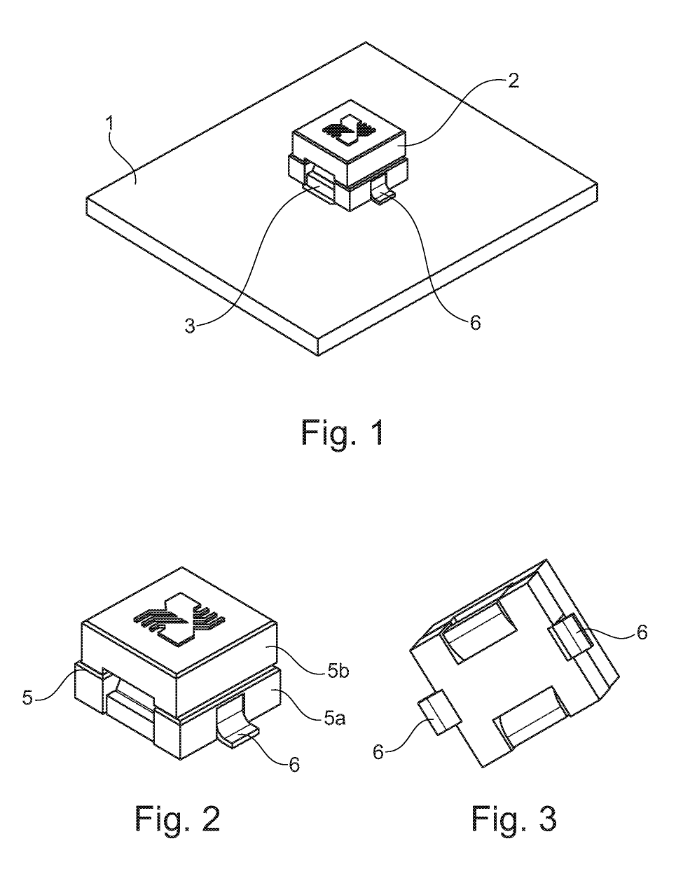

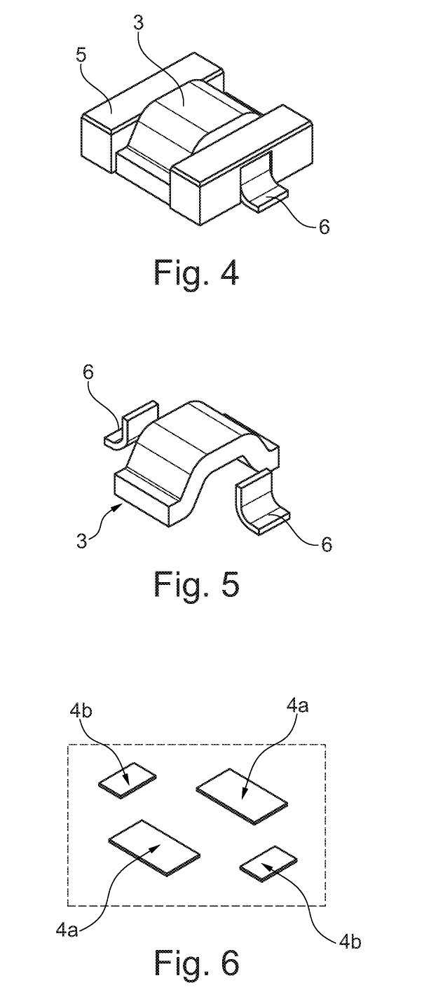

FIG. 1 schematically shows a printed circuit board 1 having a thermal fuse 2, which is shown in more detail in FIGS. 2 to 5. Printed circuit boards are sometimes also referred to as circuit boards. In addition to the thermal fuse 2, the printed circuit board 1 bears further elements of the electrical circuit, in particular at least one power semiconductor, for example a MOSFET, which are not shown for the sake of simplicity.

The essential element of the thermal fuse 2 is a spring 3, which has two contact arms, which are fastened to the printed circuit board 1 in a prestressed manner. Specifically, the two contact arms of the spring 3 are soldered onto solder pads 4a of the printed circuit board 1, shown in FIG. 6. On overheating, this soldered connection loses its strength, so that at least one of the two contact arms of the spring 3 detaches from the relevant solder pads 4a of the printed circuit board 1, for example in that the spring 3 forming a contact bridge extends so that at least one of the two contact arms thereof no longer rests on one of the solder pads 4a.

So that the spring 3 cannot move in an uncontrolled manner after detaching from the solder pads 4a of the printed circuit board 1, the spring 3 is fastened to a support 5, which is fastened to the printed circuit board 1 by means of retaining elements 6. The retaining elements 6 can for example be plugged into the printed circuit board 1 or fastened thereto by a soldered connection, which loses its strength at a higher temperature than the soldered connection that connects the contact arms of the spring 3 to the solder pads 4a.

The support 5 can consist of one or more parts, for example of a lower part 5a, which is bridged by the spring 3, and an upper part 5b, which sits on the lower part 5a and covers the spring 3. The spring 3 is then retained between the upper part 5b and the lower part 5a. The lower part 5a can have cut-outs for the soldered ends of the contact arms of the spring 3, that is, can have an H-shaped main face, for example. The upper part 5b is fastened to the lower part 5a by means of an adhesive or a snap connection, for example. Even if both contact arms of the spring 3 detach from the solder pads 4a of the printed circuit board 1, the spring 3 remains fastened to the support 5, which is fastened to the printed circuit board 1 by means of the retaining elements 6.

An important feature of the printed circuit board 1 shown with the thermal fuse 2 consists in that at least one of the two solder pads 4a to which the spring 3 is soldered bears different solder material from the other solder pad 4b of the printed circuit board 1, which are soldered to other circuit elements, in particular a power semiconductor (not shown) or the retaining elements 6 of the support 5. The soldered connection that connects one of the contact arms of the spring 3 to the printed circuit board 1 therefore loses its strength at a lower temperature, for example a temperature 10 K lower, than the solder material on the other solder pad 4b of the printed circuit board 1.

For example, Sn96.5Au3Cu0.5, which has a melting range of approximately 218 to 220° C., can be used as the higher-melting solder. Bi58Sn, which loses its strength at 139° C., or a mixture of Sn96.5Au3Cu0.5 and Bi58Sn, for example, can used as the lower-melting soldered connections. The mixture of Sn96.5Au3Cu0.5 and Bi58Sn has a melting range of 188 to 192° C.

The solder material can be printed onto the fields provided therefor on the printed circuit board 1. For example, the higher-melting solder material, e.g., Sn96.5Au3Cu0.5, can be applied using a doctor method using a paste stencil. The lower-melting solder material, e.g., Bi58Sn, can be applied for example by a method without a stencil, in particular a jet paste printing method or a dispensing method.

One possibility is printing one or both solder pads 4a that are provided for the contact arms of the spring 3 with lower-melting solder and printing higher-melting solder onto the remaining solder pads of the printed circuit board 1. However, it is also possible to print all the solder pads 4a, 4b of the printed circuit board 1 with higher-melting solder, e.g., Sn96.5Au3Cu0.5, and then to print one or both of the solder pads 4a provided for fastening the contact arms of the spring 3 on the printed circuit board 1 additionally with lower-melting solder, e.g., Bi58Sn, that is, to apply a layer of lower-melting solder material to the higher-melting solder material. These two layers can mix during soldering, in particular if the soldering is carried out using reflow soldering.

While exemplary embodiments have been disclosed hereinabove, the present invention is not limited to the disclosed embodiments. Instead, this application is intended to cover any variations, uses, or adaptations of this disclosure using its general principles. Further, this application is intended to cover such departures from the present disclosure as come within known or customary practice in the art to which this invention pertains and which fall within the limits of the appended claims.

### LIST OF REFERENCE SYMBOLS

1 Printed circuit board
2 Thermal fuse
3 Spring
4a Solder pad
4b Solder pad
5 Support
5a Lower support part
5b Upper support part
6 Retaining element

What is claimed is:

1. A printed circuit board assembly, comprising:
a printed circuit board having at least one power semiconductor soldered thereon;
a thermal fuse comprising a spring having first and second contact arms, the first contact arm being fastened to a first solder pad by a first soldered connection, and the second contact arm being fastened a second solder pad by a second solder connection;
the spring being under mechanical stress, wherein at least one of the first and second contact arms moves away from a respective one of the first and second solder pads by spring force as soon as the respective one of the first and second soldered connections fails from overheating;
wherein at least one of the first and second soldered connections fails at a lower temperature and comprises a different alloy than a power semiconductor soldered connection that connects the power semiconductor to the printed circuit board.

2. The printed circuit board assembly according to claim 1, wherein the spring is fastened to a support and the support is fastened to the printed circuit board by retaining elements.

3. The printed circuit board assembly according to claim 2, wherein the support has a lower part bridged by the spring and an upper part fastened to the lower part and covering the spring.

4. A method for populating a printed circuit board, comprising:
applying a first solder material to a first solder pad of the printed circuit board;
applying a second solder material to a second solder pad of the printed circuit board, wherein the second solder material fails at a lower temperature than the first solder material;
attaching at least one power transistor to first solder pad,
attaching a mechanically prestressed spring, which has two contact arms, to the printed circuit board such that one of the contact arms makes contact with the second solder pad and the other contact arm makes contact with the first solder pad or an additional solder pad having the second solder material; and
soldering the spring and the at least one power transistor to the printed circuit board.

5. The method according to claim 4, wherein the first solder material is also applied to the second solder pad and the second solder material is applied to the second solder pad by being arranged over the first solder material.

6. The method according to claim 4, wherein the first solder material is printed.

7. The method according to claim 6, wherein the printing comprises a doctor method using a paste stencil.

8. The method according to claim 4, wherein the second solder material is printed.

9. The method according to claim 8, wherein the second solder material is applied with a jet paste printing method.

10. The method according to claim 4, wherein the soldering is carried out using reflow soldering.

11. The method according to claims 5, wherein the first solder material and the second solder material mix during reflow soldering on the second solder pad.
